(19) United States
(12) Patent Application Publication
(10) Pub. No.: US 2024/0030266 A1
(43) Pub. Date: Jan. 25, 2024

(54) STACKED SEMICONDUCTOR DEVICE INCLUDING HYBRID BONDING STRUCTURE

(71) Applicant: SK hynix Inc., Icheon-si (KR)

(72) Inventor: Pyong Su KWAG, Icheon-si (KR)

(21) Appl. No.: 18/064,134

(22) Filed: Dec. 9, 2022

(30) Foreign Application Priority Data
Jul. 22, 2022 (KR) 10-2022-0091080

(51) Int. Cl. H01L 27/146; H01L 25/065; H01L 23/00

(52) U.S. Cl. CPC H01L 27/14636; H01L 25/0657; H01L 27/14634; H01L 24/08; H01L 24/09; H01L 2225/06524; H01L 2225/06544; H01L 2224/0801; H01L 2224/08145; H01L 2224/0903; H01L 2224/09515; H01L 2924/1431; H01L 2224/02371; H01L 2224/02381

(57) ABSTRACT

A stacked semiconductor device may include a first semiconductor chip including a first bonded surface and a second semiconductor chip including a second bonded surface facing the first bonded surface, the first and second bonded surfaces being bonded to each other. The first semiconductor chip includes a first substrate, at least one first power interconnect disposed between the first substrate and the first bonded surface of the first semiconductor chip and configured to carry a power-supply voltage therethrough, and at least one first power hybrid bonding structure disposed to be in contact with the first power interconnect and configured to extend along the same path as a routing path of the first power interconnect. The second semiconductor chip includes a second substrate, at least one second power interconnect disposed between the second bonded surface and the second substrate and configured to carry a power-supply voltage therethrough, and at least one second power hybrid bonding structure disposed to be in contact with the second power interconnect and the first power hybrid bonding structure and configured to extend along the same path as a routing path of the second power interconnect.

### CROSS-REFERENCE TO RELATED APPLICATION

This patent document claims the priority and benefits of Korean patent application No. 10-2022-0091080, filed on Jul. 22, 2022, which is incorporated by reference in its entirety as part of the disclosure of this patent document.

### TECHNICAL FIELD

The technology and implementations disclosed in this patent document generally relate to a stacked semiconductor device including a hybrid bonding structure.

### BACKGROUND

Certain types of highly integrated semiconductor devices can be manufactured by stacking different semiconductor substrates or dies. For example, such semiconductor devices can be manufactured by stacking an upper substrate on a lower substrate and bonding them together.

Different circuits and elements in the upper and lower substrates are electrically connected to each other by using bonding techniques such as hybrid bonding techniques.

Highly integrated semiconductor devices include a variety of circuits formed on a chip, and thus such bonding techniques can also be used to achieve a stable power supply to those circuits.

### SUMMARY

Various embodiments of the disclosed technology relate to a semiconductor device that can achieve a stable power supply to circuits formed in and on an upper substrate and a lower substrate bonded to each other by using a hybrid bonding structure as a routing metal in a stacked semiconductor device.

In some embodiments of the disclosed technology, a stacked semiconductor device may include a first semiconductor chip including a first boned surface and a second semiconductor chip including a second boned surface facing the first bonded surface, the first and second bonded surfaces being bonded to each other. The first semiconductor chip may include a first substrate, at least one first power interconnect disposed between the first substrate and the first bonded surface of the first semiconductor chip and configured to carry a power-supply voltage therethrough, and at least one first power hybrid bonding structure disposed to be in contact with the first power interconnect and configured to extend along the same path as a routing path of the first power interconnect. The second semiconductor chip may include a second substrate, at least one second power interconnect disposed between the second bonded surface and the second substrate and configured to carry a power-supply voltage therethrough, and at least one second power hybrid bonding structure disposed to be in contact with the second power interconnect and the first power hybrid bonding structure and configured to extend along the same path as a routing path of the second power interconnect.

In some embodiments of the disclosed technology, a stacked semiconductor device may include a first semiconductor chip and a second semiconductor chip, facing surfaces of which are bonded to each other. The first semiconductor chip may include a first substrate, at least one first power interconnect disposed between the first substrate and a bonded surface of the first semiconductor chip and the second semiconductor chip and configured to transmit a power-supply voltage, and at least one first power hybrid bonding structure disposed to be in contact with the first power interconnect and configured to extend along the same path as a routing path of the first power interconnect. The second semiconductor chip may include a second substrate, at least one second power interconnect disposed between the bonded surface and the second substrate and configured to transmit a power-supply voltage, and at least one second power hybrid bonding structure disposed to be in contact with the second power interconnect and the first power hybrid bonding structure and configured to extend along the same path as a routing path of the second power interconnect.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a schematic diagram illustrating an example of a hybrid bonding structure that can be used in a stacked semiconductor device based on some implementations of the disclosed technology.

FIG. 2 is a plan view illustrating examples of power interconnects and power hybrid bonding structures shown in FIG. 1 based on some implementations of the disclosed technology.

FIG. 3 is a schematic diagram illustrating an example of a hybrid bonding structure that can be used in a stacked semiconductor device based on some other implementations of the disclosed technology.

FIG. 4 is an example plan view illustrating power hybrid bonding structures of a first semiconductor chip illustrated in FIG. 3 and power hybrid bonding structures of a second semiconductor chip illustrated in FIG. 3 are connected to each other in a zigzag pattern based on some implementations of the disclosed technology.

FIG. 5 is a schematic diagram illustrating how electric fields affect a pixel array through a space formed between power hybrid bonding structures that are not formed in a zigzag pattern.

### DETAILED DESCRIPTION

This patent document provides implementations and examples of a stacked semiconductor device including a hybrid bonding structure that may be used to substantially address one or more technical or engineering issues and mitigate limitations or disadvantages encountered in some other stacked semiconductor devices. Some implementations of the disclosed technology suggest designs of a semiconductor device that can achieve a stable power supply to circuits formed in and on an upper substrate and a lower substrate bonded to each other by using a hybrid bonding structure as a routing metal in a stacked semiconductor device. The disclosed technology provides various implementations of a stacked semiconductor device that can achieve stably supply power to circuits formed in each of an upper substrate and a lower substrate bonded to each other.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

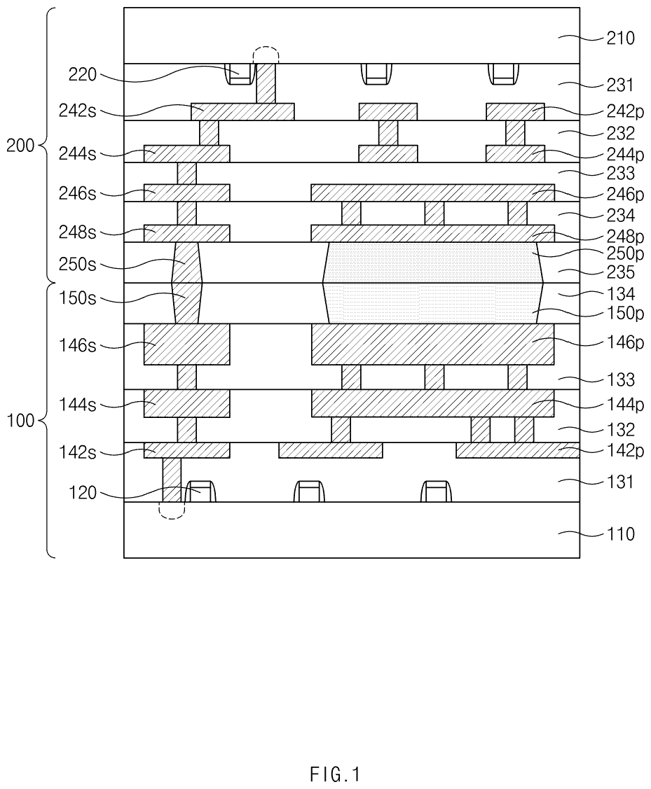

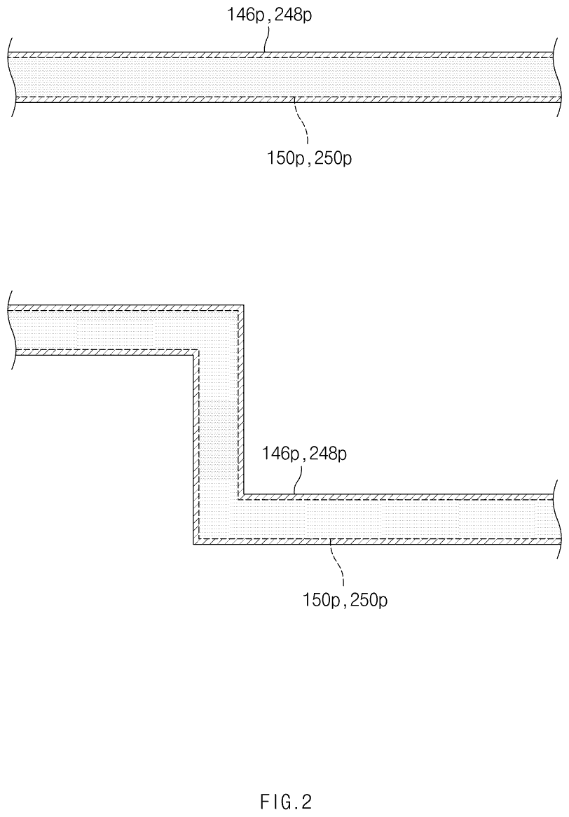

FIG. 1 is a schematic diagram illustrating an example of a hybrid bonding structure that can be used in a stacked semiconductor device based on some implementations of the disclosed technology. FIG. 2 is a plan view illustrating examples of power interconnects or power wires and power hybrid bonding structures shown in FIG. 1 based on some implementations of the disclosed technology.

Referring to FIGS. 1 and 2, a semiconductor device may include a first semiconductor chip 100 and a second semiconductor chip 200 that are stacked over each other and are electrically connected with each other. Surfaces of the first semiconductor chip 100 and the second semiconductor chip 200 that face each other may be physically bonded to each other. The first semiconductor chip 100 and the second semiconductor chip 200 may be electrically connected to each other through a hybrid bonding structure at the bonded surfaces.

The first semiconductor chip 100 may include a first substrate 110, a first circuit 120, first insulation layers 131 to 134, first power interconnects 142p to 146p, first signal interconnects 142s to 146s, a first power hybrid bonding structure 150p, and a first signal hybrid bonding structure 150s.

The first substrate 110 may include a first surface and a second surface opposite to each other, and may include silicon, silicon germanium, silicon carbide, silicon oxide, or a combination of two or more of silicon, silicon germanium, silicon carbide, and silicon oxide.

The first circuit 120 may be formed over the first substrate 110, and may be used to process input signals. Although a limited number of transistors are illustrated in FIG. 1 by way of example, the disclosed technology is not limited thereto. In some implementations, the first circuit 120 may include logic circuits that can be used to process signals received through the first signal interconnects 142s to 146s and transmit the processed signals through the first signal interconnects 142s to 146s. In addition, the first circuit 120 may operate using power supplied through the first power interconnects 142p to 146p.

The first insulation layers 131 to 134 may include interlayer insulation layers that insulate the first circuit 120, the first power interconnects 142p to 146p, the first signal interconnects 142s to 146s, the first power hybrid bonding structure 150p, and the first signal hybrid bonding structure 150s, which are stacked together in the first semiconductor chip 100, from each other, thereby preventing electrical short-circuit between them.

The first power interconnects 142p to 146p may be connected to the first power hybrid bonding structure 150p to supply an operation power to the first circuit 120 or to supply a bias power to the first substrate 110. The first signal interconnects 142s to 146s may be connected to the first signal hybrid bonding structure 150s to transmit a signal from the first signal hybrid bonding structure 150s to the first circuit 120 or to transmit a signal from the first circuit 120 to the first signal hybrid bonding structure 150s. The first power interconnects 142p to 146p and the first signal interconnects 142s to 146s may be formed between the first insulation layers 131 to 134. The first power interconnects 142p to 146p and the first signal interconnects 142s to 146s may include a metal such as copper (Cu).

The first power hybrid bonding structure 150p may include a first surface bonded to a second power hybrid bonding structure 250p of the second semiconductor chip 200, and a second surface opposite to the first surface and bonded to the uppermost power interconnect 146p from among the first power interconnects 142p to 146p, so that the first power hybrid bonding structure 150p may provide a power-supply path between the first semiconductor chip 100 and the second semiconductor chip 200. The first power hybrid bonding structure 150p may be formed to extend along the same path as a routing path of the power interconnect 146p.

In an implementation where a hybrid bonding structure is formed in a via shape so as to connect the interconnects to each other, a power hybrid bonding structure is formed to extend in the same direction and has the same shape as the power interconnect. For example, as shown in FIG. 2, when the power interconnect 146p is formed to extend in a first direction and has a straight line shape, the first power hybrid bonding structure 150p may also extend in the first direction and has a straight line shape in the same manner as the power interconnect 146p. In addition, when the power interconnect 146p is formed to extend in a bent line shape, the first power hybrid bonding structure 150p may also be formed to extend in a bent line shape in the same manner as in the power interconnect 146p.

Although FIG. 2 illustrates that a critical dimension (CD) of the first hybrid bonding structure 150p is smaller than a critical dimension (CD) of the power interconnect 146p to distinguish the first power hybrid bonding structure 150p from the power interconnect 146p, the disclosed technology is not limited thereto. For example, the first power hybrid bonding structure 150p and the power interconnect 146p may be formed to have the same critical dimension (CD). Alternatively, the CD of the first power hybrid bonding structure 150p may be larger than the CD of the power interconnect 146p.

The first signal hybrid bonding structure 150s may include a first surface bonded to a second signal hybrid bonding structure 250s of the second semiconductor chip 200, and a second surface opposite to the first surface and bonded to the uppermost signal interconnect 146s from among the first signal interconnects 142s to 146s, so that the first signal hybrid bonding structure 150s may provide a signal transmission path between the first semiconductor chip 100 and the second semiconductor chip 200. Unlike the first power hybrid bonding structure 150p, the first signal hybrid bonding structure 150s may be formed in a via shape so that the first signal hybrid bonding structure 150s may be connected to any one point or portion of the signal interconnect 146s.

The second semiconductor chip 200 may include a second substrate 210, a second circuit 220, second insulation layers 231 to 235, second power interconnects 242p to 248p, second signal interconnects 242s to 248s, a second power hybrid bonding structure 250p, and a second signal hybrid bonding structure 250s.

The second substrate 210 may include silicon, silicon germanium, silicon carbide, silicon oxide, or a combination of two or more of silicon, silicon germanium, silicon carbide, and silicon oxide. The second circuit 220 may be formed over the second substrate 210, and may be used to process input signals. For example, the second circuit 220 may include logic circuits that can be used to process signals received through the second signal interconnects 242s to 248s and transmit the processed signals through the second signal interconnects 242s to 248s. Alternatively, when the second substrate 210 includes photoelectric conversion elements for converting incident light into an electrical signal, the second circuit 220 may include pixel transistors that read out pixel signals generated by the photoelectric conversion elements of the second substrate 210. In addition, the second circuit 220 may operate using power supplied through the second power interconnects 242p to 248p.

The second insulation layers 231 to 235 may include interlayer insulation layers that insulate the second circuit 220, the second power interconnects 242p to 248p, the second signal interconnects 242s to 248s, the second power hybrid bonding structure 250p, and the second signal hybrid bonding structure 250s, which are stacked together in the second semiconductor chip 200, from each other, thereby preventing electrical short-circuit between them.

The second power interconnects 242p to 248p may supply an operation power to the second circuit 220 or may supply a bias power to the second substrate 210. The second signal interconnects 242s to 248s may be connected to the second signal hybrid bonding structure 250s to transmit a signal from the second signal hybrid bonding structure 250s to the second circuit 220 or to transmit a signal from the second circuit 220 to the second signal hybrid bonding structure 250s. The second power interconnects 242p to 248p and the second signal interconnects 242s to 248s may be formed between the second insulation layers 231 to 235. The second power interconnects 242p to 248p and the second signal interconnects 242s to 248s may include a metal such as copper (Cu).

The second power hybrid bonding structure 250p may include a first surface bonded to a first power hybrid bonding structure 150p of the first semiconductor chip 100, and a second surface opposite to the first surface and bonded to the uppermost power interconnect 248p from among the second power interconnects 242p to 248p, so that the second power hybrid bonding structure 250p may provide a power-supply path between the first semiconductor chip 100 and the second semiconductor chip 200. In the same manner as in the first power hybrid bonding structure 150p, the second power hybrid bonding structure 250p may be formed to extend along the same path as a routing path of the power interconnect 248p. That is, as shown in FIG. 2, the second power hybrid bonding structure 250p may be formed to extend in the same direction and/or have the same shape as the power interconnect 248p. In some implementations, the second power hybrid bonding structure 250p and the first power hybrid bonding structure 150p may be formed symmetrically with respect to the bonding surface.

The second signal hybrid bonding structure 250s may include a first surface bonded to the first signal hybrid bonding structure 150s of the first semiconductor chip 100, and a second surface opposite to the first surface and bonded to the uppermost signal interconnect 248s from among the second signal interconnects 242s to 248s, so that the second signal hybrid bonding structure 250s may provide a signal transmission path between the first semiconductor chip 100 and the second semiconductor chip 200. In the same manner as the first signal hybrid bonding structure 150s, the second signal hybrid bonding structure 250s may be formed in a via shape so that the second signal hybrid bonding structure 250s may be connected to any one point or portion of the signal interconnect 248s. The second signal hybrid bonding structure 250s and the first signal hybrid bonding structure 150s may be formed symmetrically with respect to the bonding surface.

As discussed above, the power hybrid bonding structures 150p and 250p may be formed in the same shape as the power interconnects 146p and 248p to which the power hybrid bonding structures 150p and 250p are respectively bonded, so that a thickness of a metal interconnect or a metal line that provides a power-supply voltage at a bonded surface between the first semiconductor chip 100 and the second semiconductor chip 200 may be equal to the sum of thicknesses of the power interconnects 146p and 248p and thicknesses of the hybrid bonding structures 150p and 250p. Therefore, the semiconductor device based on some implementations of the disclosed technology can reduce or minimize the resistance of the metal interconnects required for supplying a power-supply voltage at a bonded surface between the first semiconductor chip 100 and the second semiconductor chip 200, thereby achieving a stable power supply between the stacked semiconductor chips 100 and 200.

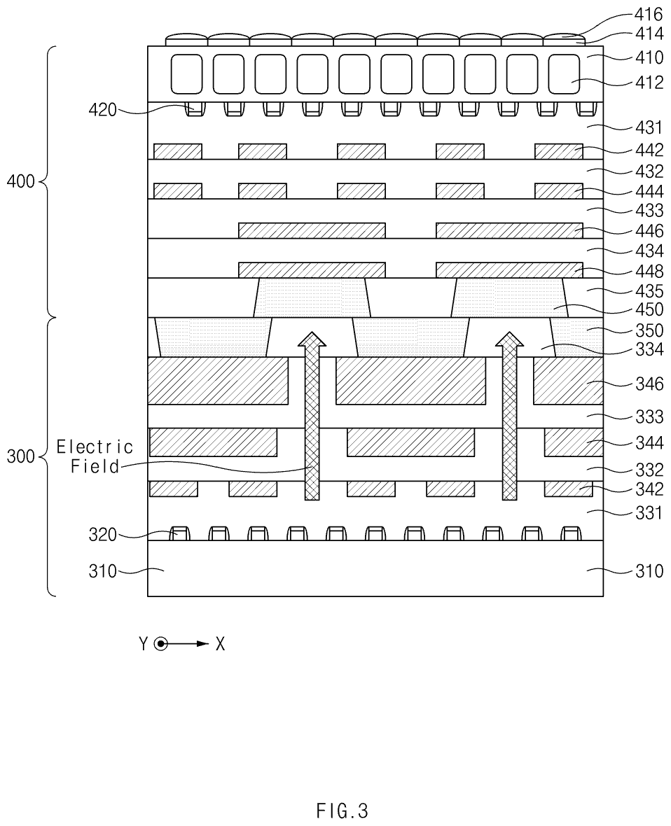

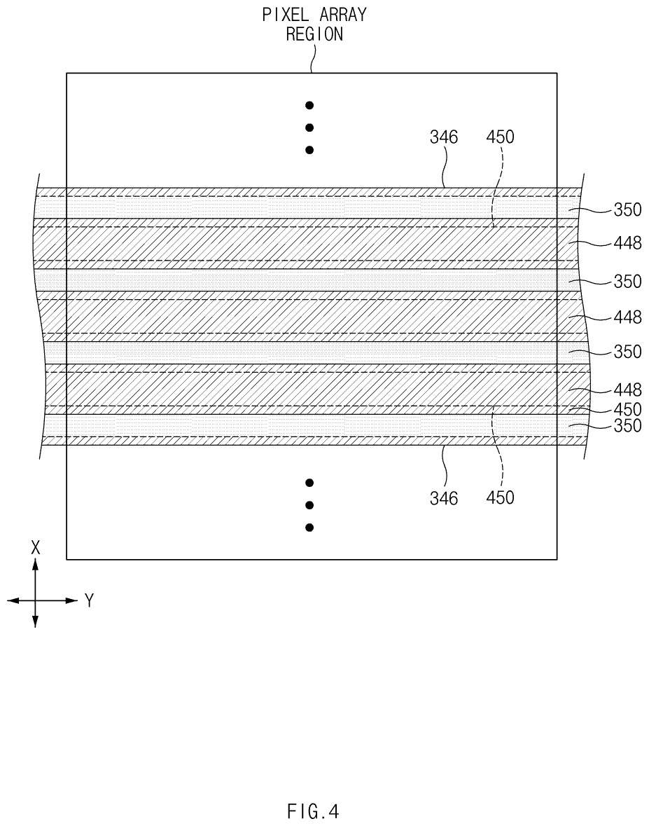

FIG. 3 is a schematic diagram illustrating an example of a hybrid bonding structure that can be used in a semiconductor device based on other implementations of the disclosed technology. FIG. 4 is a plan view illustrating the connection between power hybrid bonding structures of the first and second semiconductor chips shown in FIG. 3.

Referring to FIGS. 3 and 4, a semiconductor device may include a first semiconductor chip 300 and a second semiconductor chip 400. Surfaces of the first semiconductor chip 300 and the second semiconductor chip 400 that face each other may be physically bonded to each other. The first semiconductor chip 300 and the second semiconductor chip 400 may be electrically connected to each other through a hybrid bonding structure at the bonded surfaces.

The semiconductor device may include an image sensing device that generates an image by converting incident light into electrical signals (photoelectric conversion). For example, the second semiconductor chip 400 may include a pixel array configured to generate a pixel signal through the photoelectric conversion, and the first semiconductor chip 300 may include a logic circuit for generating an image by processing the pixel signal generated by the pixel array of the second semiconductor chip 400. That is, FIGS. 3 and 4 show an example implementation where the power hybrid bonding structure shown in FIG. 1 is applied to the image sensing device.

The first semiconductor chip 300 may include a first substrate 310, a first circuit 320, first insulation layers 331 to 334, first interconnects 342 to 346, and a first power hybrid bonding structure 350.

The first substrate 310 may include silicon, silicon germanium, silicon carbide, silicon oxide, or a combination of two or more of silicon, silicon germanium, silicon carbide, and silicon oxide. The first circuit 320 may include a logic circuit which receives a pixel signal generated by the second semiconductor chip 400 and then generates an image by processing the pixel signal.

The first insulation layers 331 to 334 may include interlayer insulation layers that insulate the first circuit 320, the first interconnects 342p to 346p, and the first power hybrid bonding structure 350, which are formed to be stacked in the first semiconductor chip 300, from each other, thereby preventing electrical short-circuit from occurring therebetween.

The first interconnects 342 to 346 may include power interconnects connected to the first power hybrid bonding structure 350 to supply an operation power to the first circuit 320 or to supply a bias power to the first substrate 320, and signal interconnects connected to the first circuit 320 to transfer a signal for image processing. Each of the first interconnects 342 to 346 may be formed in a line shape extending in the first direction (Y-axis direction). The interconnects 346 in the uppermost layer from among the first interconnects 342 to 346 may be spaced apart from each other by a predetermined distance, and a ground voltage may be applied to the interconnects 346. The interconnects 346 may extend across a pixel array region of the image sensing device in the first direction.

The first power hybrid bonding structure 350 may be bonded to the second power hybrid bonding structure 450 of the second semiconductor chip 400 to provide a power-supply path between the first semiconductor chip 300 and the second semiconductor chip 400. As can be seen from FIGS. 1 and 2, the first power hybrid bonding structure 350 may be formed to be in contact with a top surface of the power interconnect 346 disposed in the uppermost layer from among the power interconnects, and may be formed to extend along the same path as the routing path of the corresponding power interconnect 346. Accordingly, the first power hybrid bonding structures 350 may be spaced apart from each other by a predetermined distance while extending in the first direction in the pixel array region in the same manner as in the power interconnect 346.

The second semiconductor chip 400 may include a second substrate 410, a second circuit 420, second insulation layers 431 to 435, second interconnects 442 to 448, and a second power hybrid bonding structure 450.

The second substrate 410 may include silicon, silicon germanium, silicon carbide, silicon oxide, or a combination of two or more of silicon, silicon germanium, silicon carbide, and silicon oxide. Photoelectric conversion elements 412 for converting an optical signal into an electrical signal may be formed in the second substrate 410. Color filters 414 and microlenses 416 may be disposed over the back surface of the second substrate 410. The light incident upon the photoelectric conversion elements 412 in the second substrate 410 through the microlenses 416 and the color filters 414 may be converted into an electrical signal.

The second circuit 420 may include pixel transistors for reading out the electrical signal (photocharges) generated by the photoelectric conversion elements 412 of the second substrate 410. The second insulation layers 431 to 435 may include interlayer insulation layers that insulate the second circuit 420, the second interconnects 442 to 448, and the first power hybrid bonding structure 450, which are formed to be stacked in the second semiconductor chip 400, from each other, thereby preventing electrical short-circuit from occurring therebetween.

The second interconnects 442 to 448 may include power interconnects connected to the second power hybrid bonding structure 450 to supply an operation power to the second circuit 420 or to supply a bias power to the second substrate 410, and signal interconnects connected to the second circuit 420 to transfer a pixel signal. Each of the second interconnects 442 to 448 may be formed in a line shape extending in the first direction (Y-axis direction). The interconnects 448 in the uppermost layer from among the second interconnects 442 to 448 may be spaced apart from each other by a predetermined distance, and a ground voltage may be applied to the interconnects 448. The interconnects 448 may extend across a pixel array region of the image sensing device in the first direction. In addition, the interconnects 448 of the second semiconductor chip 400 and the interconnects 346 of the first semiconductor chip 300 may arranged in a zigzag pattern with partially overlapping in the second direction (X-axis direction).

The second power hybrid bonding structure 450 may be bonded to the first power hybrid bonding structure 350 of the first semiconductor chip 300 to provide a power-supply path between the first semiconductor chip 300 and the second semiconductor chip 400. In the same manner as in the first power hybrid bonding structure 350, the second power hybrid bonding structure 450 may also be formed to be in contact with a top surface of the power interconnect 448 disposed in the uppermost layer from among the power interconnects, and may be formed to extend along the same path as the routing path of the corresponding power interconnect 448. Accordingly, the second power hybrid bonding structures 450 may be formed to be spaced apart from each other by a predetermined distance while extending in the first direction in the pixel array region in the same manner as in the power interconnect 448.

The second power hybrid bonding structures 450 may be arranged in a zigzag pattern with the first power hybrid bonding structures 350 while predetermined regions (both ends) of the second power hybrid bonding structures 450 overlap with the first power hybrid bonding structures 350 in the second direction (e.g., 350 and 450 in FIG. 3). As described above, the first power hybrid bonding structures 350 and the second power hybrid bonding structures 450 may be arranged in a zigzag pattern, and at the same time predetermined regions of the first power hybrid bonding structures 350 may overlap with predetermined regions of the second power hybrid bonding structures 450 while being in contact with the predetermined regions of the second power hybrid bonding structures 450. As a result, the first power hybrid bonding structures 350 and the second power hybrid bonding structures 450 can cover the entire pixel array region, as shown in FIG. 4.

As can be seen from FIG. 4, the power hybrid bonding structures 350 and 450 may be supplied the ground voltage while covering the entire pixel array region, thereby preventing image defects caused by an electric field generated in the first circuits 320.

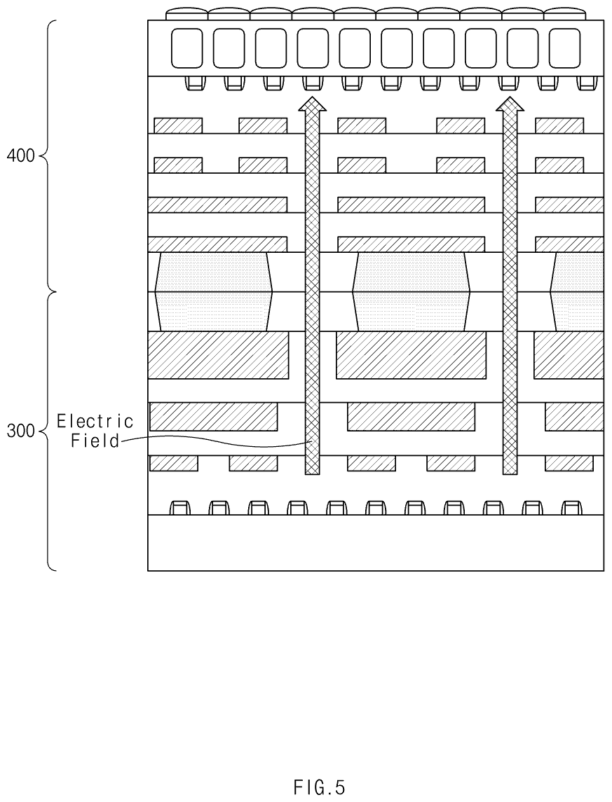

FIG. 5 is a schematic diagram illustrating how electric fields affect a pixel array through a space formed between the power hybrid bonding structures that are not formed in a zigzag pattern.

In a situation where each of the interconnects is formed in a line shape extending in a first direction in the stacked image sensing device as shown in FIG. 3, when the electric field affects the pixel array through a space between the interconnects as shown in FIG. 5, noises corresponding to the shape of the interconnects may be added to an image due to occurrence of the electric field. For example, although the substantially same light is incident upon the pixel array, stripe pattern(s) in the first direction may occur in the image.

In an embodiment of the disclosed technology, in order to prevent the above-described phenomenon, power hybrid bonding structures entirely cover the pixel array region and at the same time the ground voltage is applied to the corresponding power hybrid bonding structures, so that the power hybrid bonding structures can be used as a shielding layer for blocking the electric field. As described above, the power hybrid bonding structures are used as the shielding layer for blocking the electric field from being introduced into the pixel array, so that image defects caused by such electric field can be prevented.

As is apparent from the above description, the stacked semiconductor device based on some implementations of the disclosed technology can achieve a stable power supply to circuits formed in each of the upper substrate and the lower substrate bonded to each other.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. A stacked semiconductor device comprising:
a first semiconductor chip including a first bonded surface and a second semiconductor chip including a second bonded surface facing the first bonded surface, the first and second bonded surfaces being bonded to each other,
wherein the first semiconductor chip includes:
a first substrate;
at least one first power interconnect disposed between the first substrate and the first bonded surface of the first semiconductor chip, and configured to carry a power-supply voltage therethrough; and
at least one first power hybrid bonding structure disposed to be in contact with the first power interconnect, and configured to extend along the same path as a routing path of the first power interconnect,
wherein the second semiconductor chip includes:
a second substrate;
at least one second power interconnect disposed between the second bonded surface and the second substrate, and configured to carry a power-supply voltage therethrough; and
at least one second power hybrid bonding structure disposed to be in contact with the second power interconnect and the first power hybrid bonding structure, and configured to extend along the same path as a routing path of the second power interconnect.

2. The stacked semiconductor device according to claim 1, wherein:
the first and second power hybrid bonding structures are structured to be symmetrical to each other with respect to the bonded surface.

3. The stacked semiconductor device according to claim 1, wherein:
each of the first and second power hybrid bonding structures is formed to extend in a straight line shape in a first direction.

4. The stacked semiconductor device according to claim 1, wherein:
each of the first and second power hybrid bonding structures is formed to have a bent line shape or continuous bent line shapes connected to one another.

5. The stacked semiconductor device according to claim 1, further comprising:
at least one first signal interconnect disposed between the first bonded surface and the first substrate, and configured to carry a signal therethrough;
at least one first signal hybrid bonding structure disposed on the first signal interconnect and having a via shape in contact with the first signal interconnect;
at least one second signal interconnect disposed between the second bonded surface and the second substrate, and configured to carry a signal therethrough; and
at least one second signal hybrid bonding structure having a via shape in contact with the second signal interconnect and the first signal hybrid bonding structure.

6. The stacked semiconductor device according to claim 1, wherein the second semiconductor chip includes:
a pixel array configured to generate a pixel signal by converting incident light into the pixel signal.

7. The stacked semiconductor device according to claim 6, wherein the at least one first power hybrid bonding structure includes:
a plurality of power hybrid bonding structures, each power hybrid bonding structure extending in a line shape in a first direction, disposed to be spaced apart from each other in a second direction perpendicular to the first direction.

8. The stacked semiconductor device according to claim 7, wherein:
the at least one first power hybrid bonding structure extends across the pixel array in the first direction.

9. The stacked semiconductor device according to claim 7, wherein the at least one second power hybrid bonding structure includes:
a plurality of power hybrid bonding structures, each power hybrid bonding structure extending in a line shape in the first direction and being disposed to be spaced apart from each other in the second direction, wherein the at least one second power hybrid bonding structure and the at least one first power hybrid bonding structure partially overlap with each other in the second direction.

10. The stacked semiconductor device according to claim 1, wherein:
the at least one first power hybrid bonding structure and the at least one second power hybrid bonding structure adjacent to each other are disposed such that a predetermined region of the first power hybrid bonding structure is in contact with a predetermined region of the second power hybrid bonding structure.

11. The stacked semiconductor device according to claim 9, wherein:
the at least one first power hybrid bonding structure and the at least one second power hybrid bonding structure together entirely cover the pixel array.

12. The stacked semiconductor device according to claim 6, wherein:
the at least one first power hybrid bonding structure and the at least one second power hybrid bonding structure are configured to receive a ground voltage.

13. The stacked semiconductor device according to claim 7, wherein the at least one second power hybrid bonding structure includes:
a plurality of power hybrid bonding structures, each power hybrid bonding structure extending in a line shape in the first direction and being disposed to be spaced apart from each other in the second direction, wherein the at least one second power hybrid bonding structure and the at least one first power hybrid bonding structure adjacent to the at least one second power hybrid bonding structure overlap with each other at their edges.

14. The stacked semiconductor device according to claim 13, wherein:
an edge of the at least one first power hybrid bonding structure is in contact with an edge of the at least one second power hybrid bonding structure adjacent to each other.
